(19) United States
(12) Patent Application Publication
(10) Pub. No.: US 2024/0411234 A1
(43) Pub. Date: Dec. 12, 2024

(54) METHOD FOR MACHINING A WORKPIECE

(71) Applicant: Carl Zeiss SMT GmbH, Oberkochen (DE)

(72) Inventors: Tobias MEISCH, Essingen (DE); Fabian SCHUSTER, Bad Buchau (DE); Christof JALICS, Heidenheim (DE)

(21) Appl. No.: 18/807,439

(22) Filed: Aug. 16, 2024

Related U.S. Application Data
(63) Continuation of application No. PCT/EP2023/053790, filed on Feb. 15, 2023.

(30) Foreign Application Priority Data
Mar. 1, 2022 (DE) 102022202059.6

(51) Int. Cl. G03F 7/00

(52) U.S. Cl. CPC G03F 7/70875; G03F 7/70891

(57) ABSTRACT

A method for processing a workpiece (17) in a processing process, preferably in a photolithographic structuring process. The processing of the workpiece (17) includes controlling the temperature of the workpiece (17). In the process, the temperature of the workpiece (17) is controlled by streaming a fluid (27) through at least one channel (26) formed inside the workpiece (17).

### CROSS-REFERENCE TO RELATED APPLICATION

This is a Continuation of International Application PCT/EP2023/053790, which has an international filing date of Feb. 15, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 102022202059.6 filed Mar. 1, 2022.

### FIELD

The invention relates to a method for processing a workpiece in a processing process, preferably in a lithographic structuring process, the processing of the workpiece including controlling the temperature (heating and/or cooling) of the workpiece.

### BACKGROUND

During processing processes, e.g. during the structuring of a workpiece, it is frequently necessary to control the temperature of the workpiece. If the workpiece is machined in the processing process and heat is introduced into the workpiece in so doing, temperature control in the form of cooling can be performed, for which compressed-air nozzles, among other things, can be used. The control of the temperature can also involve heating the workpiece, for example if the processing process includes a step with a heat treatment (tempering). Such a heat treatment can be performed on the workpiece itself or on a resist layer that is freshly applied to the workpiece and still has a residual solvent content, in order to bake the resist layer and drive out the solvent. The resist layer may be e.g. a photoresist layer, which is baked in what is referred to as a soft bake or pre-bake step of a photolithographic process (cf. e.g. “https://imicromaterials.com/technical/lithography-process-overview” or “http://www.lithoguru.com/scientist/lithobasics.html”) and then structured.

To bake such a photoresist layer, the workpiece, in this case typically a wafer, can be introduced into a convection oven or heated on what is referred to as a hotplate (a hot, typically metallic plate). In the case of heating using a hotplate, the wafer is placed onto the hotplate or held at a small spacing from the surface of the hotplate, i.e. the transfer of heat takes place by conduction and is therefore relatively quick. By contrast, heating the wafer in a convection oven is much slower: cf. “https://www.microchemicals.com/technical_information/softbake_photoresist.pdf”.

In the case of thicker resist layers, it is generally not expedient to dry them in a convection oven, since the dried resist surface makes it harder to quickly evaporate the solvent. In this case, the use of a hotplate is advantageous, since with a hotplate the solvent is driven out of the resist layer from underneath (cf. “https://www.allresist.de/faqphotoresists-0080temperungnachbeschichtung/”).

EP 0 206 938 B1 has disclosed a method for forming a binary germanosilicate glass on a wafer which contains integrated circuits. During the method, a solution containing a solvent is deposited on the wafer and the wafer is made to spin, until excess solution is spun off of the wafer and the remaining solution is in equilibrium. The wafer and the remaining solution are baked until the solvent is driven off and a binary germanosilicate glass is formed. The baking step may be one bake step at least at 400° C. to drive out all of the solvent and to produce the oxides of the binary glass.

DE3539201 C2 has disclosed an X-ray lithography mask having a mask carrier, in the form of a thin film, for an absorber material. The thin film contains aluminum nitride, which is to serve among other things for enabling a heat treatment, or baking, with very high precision, because the coefficient of thermal expansion of the aluminum nitride has approximately the same value as that of the substrate undergoing the heat treatment.

To control the temperature of a workpiece, it is typically necessary to introduce it into a device provided specially for this purpose, for example an oven. The workpiece therefore, for the temperature control, generally cannot remain in a processing machine in which the processing process or a step of the processing process (e.g. applying the resist, developing, etching, etc.) is carried out.

### SUMMARY

An object of the invention is to provide a method which makes it possible to control the temperature of a workpiece in a processing process particularly efficiently.

This and other objects are achieved by a method of the type mentioned in the introduction, comprising: controlling the temperature of the workpiece by streaming (temperature-controlled) fluid, i.e. a (temperature-controlled) liquid or a (temperature-controlled) gas, through at least one channel formed inside the workpiece.

In the method according to the invention, it is proposed that a fluid is streamed through a channel, which is present in the workpiece or is formed specifically for this purpose in the workpiece and is typically intended to have a fluid flow through it while the workpiece is in operation, e.g. a cooling channel, in at least one step of the processing process. In this case, the fluid that streams through the channel and itself is temperature-controlled, i.e. has a predefined temperature, is used to control the temperature of the workpiece. In this way, channels which are provided in any case in the workpiece can be used in one or more steps of the processing process to control the temperature of the workpiece. The workpiece can therefore remain in a respective processing machine, which is intended e.g. for baking, developing, etching, etc. of the workpiece, and its temperature can be controlled without additional handling. In this way, it is both the case that the value stream is simplified and the machinery is minimized.

In one variant of the method, a layer, which is baked while the temperature of the workpiece is being controlled in at least one baking step, is applied to the workpiece. The baking may, for example, serve to connect two or more constituent parts of the layer to one another, as is the case for example for the binary glass described in EP 0 206 938 B1. The one or more channels are in this case preferably made in the workpiece in the vicinity of the layer, in order to ensure a good transfer of heat from the fluid to the layer.

In a development of this variant, the layer is a photoresist layer, which is intended for structuring in the photolithographic structuring process. For the baking of such a photoresist layer, generally temperatures of the order of magnitude of approximately 100° C. are sufficient, and these temperatures can be easily reached using a fluid-type heating source, in particular a liquid-type heating source. The liquid which streams through the channel may in this case, for example, be water.

In a development of this variant, the baking step is carried out before an exposure step for exposing the photoresist layer, in order to drive solvent out of the photoresist layer. The baking step is in this case what is referred to as a soft bake, which is carried out on the unstructured layer before an exposure step and before a development step which follows on from the exposure step, and before an etching step which follows on from the development step.

By controlling the temperature with the flow of a fluid through the one or more channels, the heat energy comes from the workpiece itself and not from the surrounding area, as would be the case for temperature control in an oven. For driving the solvent out of the layer, it is considerably more efficient to drive the solvent out of the depth of the layer in the direction of the surface of the layer than in the opposite direction. Although such driving out of solvent from the bottom side to the top side of the layer is also performed in the case of the baking on a hotplate that was described above, baking on a hotplate can typically be carried out only on layers that have been deposited on flat, relatively small surfaces. By contrast, streaming a fluid, in accordance with the invention, through channels made in the workpiece can also be carried out on large workpieces. In addition, in the case of the method according to the invention, the surface to which the layer is applied may be a curved surface or a freeform surface.

In a further variant, the baking step is carried out after an exposure step for exposing the photoresist layer. In this case, the baking step is what is referred to as a post-exposure bake step or a hard bake step. A post-exposure bake step may be necessary in order to increase the diffusion in the photoresist layer after the exposure step. The exposure step and the (optional) post-exposure bake step are followed by the development step, which is followed by the hard bake step, during which the solvent remaining is driven out and the photoresist layer is cured. Even during the hard bake step, the temperature in the layer is of the order of magnitude of approximately 100° C., with the result that it is generally readily possible to stream a correspondingly temperature-controlled fluid through the one or more channels.

In a further variant, the workpiece is in the form of a mirror and the layer to be baked is preferably applied to an optical surface of the mirror. The optical surface of the mirror is that surface of the mirror on which the radiation to be reflected by the mirror is incident. A reflective coating can be applied to the optical surface, but depending on the material of the mirror and the wavelength of the incident radiation this is not absolutely necessary.

In a further variant, the mirror has a substrate in which the at least one channel is formed. The substrate in which the one or more channels are made may, for example, be glass, a glass ceramic or another material, for example a metal. The one or more channels serve in this case typically for cooling of the mirror while the mirror is in operation, i.e. it is a directly cooled mirror, as described for example in DE 10 2019 217 530 A1. In the case of such a mirror, the cooling channels typically extend in the vicinity of the optical surface and therefore make it possible to quickly and effectively control the temperature of the layer applied to the optical surface.

In a further variant, the structuring of the layer forms a structure, in particular a grating structure and/or at least one marking, on the surface of the mirror. The layer applied to the surface of the mirror or of the substrate is in this case a photoresist layer, which is structured using a lithographic structuring process in order to create the structure, for example the grating structure or the marking. The grating structure may be a binary structure, what is referred to as a blaze structure, etc. A reflective coating, for example in the form of a multilayer coating, may be applied to the grating structure in a subsequent coating process. The grating structure may perform different functions depending on the application. The marking(s) on the surface of the mirror may serve, for example, for adjustment or for alignment/positioning of the mirror. Other types of structures may also be formed on the surface of the mirror.

In a further variant, the structuring of the layer forms at least one structured electrically conductive or electrically insulating layer on at least one surface of the mirror. In this variant, the baked layer is typically also a photoresist layer, which is structured during the photolithographic process. The photoresist layer may itself form an electrically conductive or electrically insulating layer, but it is also possible for the photoresist layer to be applied to an underlying layer, which consists of an electrically conductive or an electrically insulating material. In this case, during the etching operation, portions not only of the photoresist layer but also of the underlying layer are removed, in order to structure them. In general, the photoresist layer is completely removed after the etching operation and only the structured layer of the electrically conductive or electrically insulating material still remains on the surface.

The structured electrically conductive layer can form conductor tracks or other electrically conductive structures, which can serve e.g. for actuation of electromechanical components. It is also possible for the structuring to serve to electrically insulate electrically conductive structures on the one or more surfaces of the mirror. In this case, the electrically insulating layer is used to produce insulator structures which typically serve for electrical insulation of adjacent or underlying electrically conductive structures. The structured electrically conductive or electrically insulating layer may be applied to any desired surface of the mirror, even to the optical surface, provided that the layer or the electrically conductive or insulating structures is or are positioned outside a reflective coating applied there.

In a variant, the structuring of the layer forms at least one structured passivation layer on at least one surface of the mirror. Within the meaning of this application, a passivation layer is understood to mean a protective layer which protects the substrate in the region covered by this protective layer, for example against oxidation or hydrogen-induced outgassing (HIO). The structured passivation layer may be a photoresist layer which is sintered during the baking operation, for example a photoresist which is sintered to form SiO₂ (e.g. the photoresist “Medusa 82”; cf. “https://www.allresist.com/allresist-presents-medusa-82-at-the-mne-2019-in-rhodes/”). However, the passivation layer may also be a layer which is arranged underneath the photoresist layer and portions of which are removed during the structuring of the photoresist layer. Such a passivation layer may be a polymer layer, for example a layer made of a polyimide, e.g. Durimide® from Fujifilm. As described above, the photoresist layer is generally completely removed during or after the structuring of the polymer layer, with the result that only the structured polymer layer remains on the surface.

In a further variant, the mirror is designed for use in an EUV lithography apparatus and the grating structure preferably forms a spectral filter. The radiation emitted by the EUV radiation source also contains, in addition to radiation in the EUV wavelength range, radiation in other wavelength ranges, in particular in the IR wavelength range, the propagation of which through the EUV lithography apparatus is undesired. The grating structure can serve to suppress undesired spectral components of the radiation emitted by the EUV radiation source. The mirror may be a collector mirror, which serves to focus EUV radiation emitted by an EUV radiation source. However, it is also possible for other mirrors of the EUV lithography apparatus, for example mirrors in an illumination system or in a projection system of the EUV lithography apparatus, to be provided with a grating structure which serves as a spectral filter or another purpose.

To produce a grating structure which forms a spectral filter, a structuring layer may be applied to the substrate of the collector mirror, as described for example in DE 10 2018 220 629 A1, which is incorporated by reference in its entirety in the content of this application. As described in that document, the structuring layer may be a layer of photoresist, which is structured by a lithographic method. In this case, a respective baking step of the photolithographic method can be carried out in the way described above, i.e. by streaming a fluid through the one or more cooling channels formed in the substrate, in order to control the temperature of the substrate, more specifically to heat the substrate. The substrate in which the cooling channels are made may be, for example, amorphous silicon (a-Si), silicon dioxide (SiO₂), Ti, Pt, Au, Al TiOₓ, Ni, Cu, NiP, Ag, Ta or Al₂O₃. As described in DE 10 2018 220 629 A1, in order to produce the grating structure, the substrate itself can also be structured. A collector mirror having a substrate which is coated and processed in order to form a structured extraneous-light portion is also described in DE 10 2019 200 698 A1.

In a further variant, the fluid which streams through the channel has a temperature of at least 60° C. and no more than 120° C., preferably at least 80° C. and no more than 110° C. The temperature of the fluid decreases as it streams through the channel from the channel inlet to the channel outlet. The temperature of the fluid is in the temperature range specified above in the entire channel, i.e. from the channel inlet to the channel outlet. As described above, a temperature of the resist layer that is within the temperature range specified above is sufficient for the baking of a resist layer. Temperatures in the specified temperature range can be reached, for example, if water is streamed through the channel. Solvents, for example alcohols or oils, also come into consideration as liquids for streaming through the channel. A temperature-controlled gas or a mixture of temperature-controlled gases may also serve as fluid for streaming through the channel.

In a further variant, a temperature and/or a flow velocity of the fluid which streams through the at least one channel is adjusted or set to a predefined value. The temperature of the fluid is generally set when the fluid streaming through the channel is not carried in a closed circuit. In this case, the fluid is heated to the desired value before it passes through the channel. For the case in which the fluid is carried in a closed circuit, it is generally favorable to monitor the temperature of the fluid using one or more temperature sensors, in order to adjust the temperature of the fluid to a desired (setpoint) value. In this way, by controlling the temperature of the fluid, the workpiece and in particular a layer applied thereto can be very precisely brought to a predefined temperature and maintained there. In addition to the temperature of the fluid, the flow velocity of the fluid through the channel is also a parameter which can be subjected to open-loop or closed-loop control in order to influence the temperature of the workpiece as desired. The temperature of the workpiece can also be varied over time by setting the temperature and/or the flow velocity of the fluid, if this is favorable for the respective processing process.

Further features and advantages of the invention are evident from the following description of exemplary embodiments of the invention, with reference to the figures of the drawing, which show details essential to the invention, and from the claims. The individual features can each be realized individually by themselves or as a plurality in any desired combination in a variant of the invention.

### BRIEF DESCRIPTION OF THE DRAWINGS

Exemplary embodiments are illustrated in the schematic drawing and are explained in the following description. In the figures:

FIG. 1 schematically shows a meridional section of a projection exposure apparatus for EUV projection lithography,

FIG. 2A shows a schematic illustration of a collector mirror, which has a channel through which a liquid flows in order to control the temperature of the substrate in a baking step of a lithographic structuring process, and

FIGS. 2B and 2C show a schematic illustration of the collector mirror during an exposure step and after an etching step of the lithographic structuring process.

### DETAILED DESCRIPTION

In the following description of the drawings, identical reference signs are used for components that are the same or analogous or have the same or analogous function.

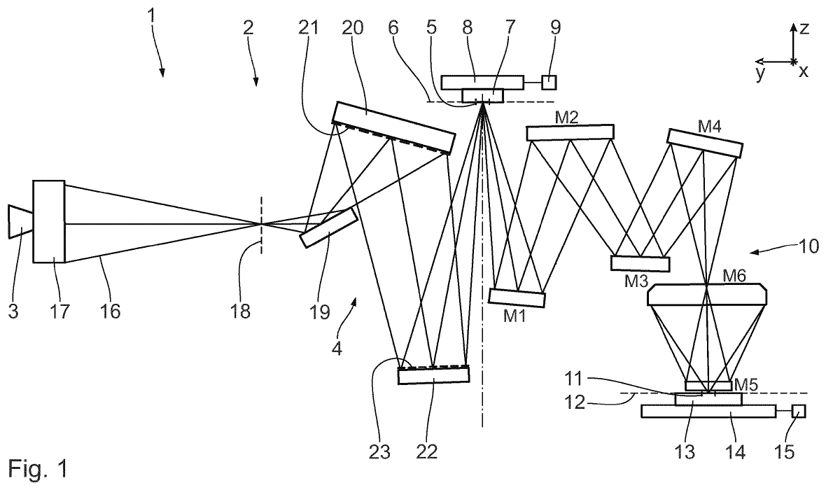

Salient components of an optical arrangement for EUV lithography in the form of a microlithographic projection exposure apparatus 1 are described by way of example below with reference to FIG. 1. The description of a basic setup of the projection exposure apparatus 1 and the components thereof should not be considered here to be restrictive.

One embodiment of an illumination system 2 of the projection exposure apparatus 1 has, in addition to a light source or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9, in particular in a scanning direction.

For explanation purposes, a Cartesian xyz-coordinate system is depicted in FIG. 1. The x-direction runs perpendicularly into the plane of the drawing. The y-direction runs horizontally and the z-direction runs vertically. The scanning direction runs along the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction. The displacement, firstly of the reticle 7 by way of the reticle displacement drive 9 and secondly of the wafer 13 by way of the wafer displacement drive 15, can be synchronized with one another.

The radiation source 3 is an EUV radiation source. The radiation source 3 emits in particular EUV radiation 16, which is also referred to as used radiation, illumination radiation or illumination light below. In particular, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 may be a free electron laser (FEL).

The illumination radiation 16 emanating from the radiation source 3 is focused by a collector mirror 17. The collector mirror 17 can be a collector mirror with one or more ellipsoidal and/or hyperboloidal reflection surfaces. The illumination radiation 16 can be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 can be structured and/or coated on the one hand to optimize its reflectivity for the used radiation and on the other hand to suppress extraneous light.

Downstream of the collector mirror 17, the illumination radiation 16 propagates through an intermediate focus in an intermediate focal plane 18. The intermediate focal plane 18 can constitute a separation between a radiation source module, comprising the radiation source 3 and the collector mirror 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. As an alternative or in addition, the deflection mirror 19 may be in the form of a spectral filter separating a used-light wavelength of the illumination radiation 16 from extraneous light having a wavelength that deviates therefrom. The first facet mirror 20 comprises a multiplicity of individual first facets 21, which are also referred to below as field facets. FIG. 1 illustrates only some of said facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 consequently forms a doubly faceted system. This fundamental principle is also referred to as a fly's eye integrator. With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optical unit 10 has an image-side numerical aperture which is greater than 0.4 or 0.5 and which can also be greater than 0.6 and which can be for example 0.7 or 0.75.

Just like the mirrors of the illumination optical unit 4, the mirrors Mi can have a highly reflective coating for the illumination radiation 16.

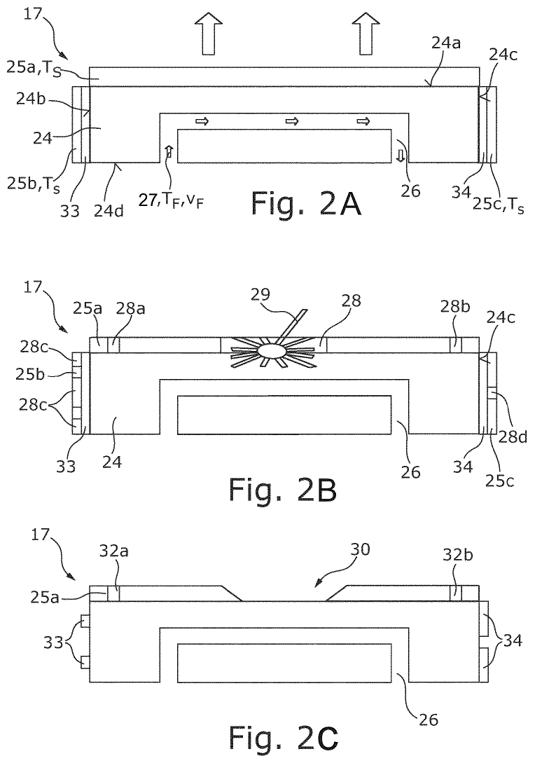

FIGS. 2A-2C show three steps of a processing process in the form of a lithographic structuring process on a workpiece in the form of the collector mirror 17 illustrated in FIG. 1. The lithographic structuring process serves for structuring of a photoresist layer 25a, which is applied to a substrate 24 of the collector mirror 17. The photoresist layer 25a was formed in a previous coating step (by spin coating) on the substrate 24, more specifically on a surface 24a of the substrate 24 that forms an optical surface of the collector mirror 17 on which the illumination radiation 16 is incident and at which the illumination radiation 16 is reflected. Two photoresist layers 25b, 25c, which are likewise to be structured in the lithographic structuring process, are also applied to a respective side face 24b, 24c of the substrate 24. A photoresist layer intended for structuring can also be applied to the back side 25d of the substrate 24.

FIG. 2A shows the collector mirror 17 during a baking step for baking the photoresist layers 25a-c (soft bake), in order to drive solvent out of the photoresist layers 25a-c. During the baking step, the photoresist layers 25a-c are heated to a temperature Tₛ of the order of magnitude of approximately 100° C. To control the temperature of the collector mirror 17 and thus of the photoresist layers 25a-c, the example shown in FIG. 2A makes use of a liquid 27, which flows through a channel 26 within the substrate 24. The channel 26 is one of multiple cooling channels made in the substrate 24. The cooling channels can be made for example by milling or in that the substrate 24 is composed of two partial bodies, as described in DE 10 2019 217 530 A1, which is incorporated by reference in its entirety in the content of this application.

In the example shown, the substrate 24 is amorphous silicon (a-Si), but may also be another material, for example silicon dioxide (SiO₂), Ti, Pt, Au, Al TiOₓ, Ni, Cu, NiP, Ag, Ta or Al₂O₃. While the collector mirror 17 is in operation in the EUV lithography apparatus 1, a cooling liquid, typically cooling water, is streamed through the channel 26, in order to cool the collector mirror 17.

In the lithographic structuring process described here, the liquid 27 is streamed through the channel 26, in order to heat the substrate 24 and thus the layers 25a-c to a desired temperature T_{S} for the baking operation. To this end, the temperature of the liquid 27 flowing through the channel 26 is controlled and the liquid is heated to a temperature T_{F} which is typically between 60° C. and 120° C. or between 80° C. and 110° C. A conventional heating device, for example in the form of a resistance heater, may be used to heat the liquid 27. The liquid 27 is fed to the channel 26 via a liquid feeding system, e.g. in the form of a flexible tube or the like, which is not depicted. Correspondingly, the liquid 27 flowing out of the channel 26 is discharged from the channel 26, or from the mirror 17, via a liquid discharging system, e.g. of the flexible tube type or the like, which is not depicted. Instead of a fluid in the form of a liquid 27, a fluid in the form of a (temperature-controlled) gas can also be used for streaming through the channel 26.

In order to as precisely as possible heat the mirror 17, and thus the photoresist layers 25a-c to be baked, to a predefined temperature T_{S} and keep it, and them, at this temperature, the temperature T_{F} of the liquid 27 as it enters the channel 26 can be set or adjusted to a predefined value. The temperature T_{F} of the liquid is typically adjusted to a predefined (setpoint) value when the liquid 27 is carried in a closed circuit and passes through the channel 26 repeatedly. In this case, there is generally at least one temperature sensor in the liquid circuit. The temperature can be set or adjusted using conventional open-loop or closed-loop controllers. The temperature Tₛ of the mirror 17, or of the respective photoresist layer 25a-c, is also influenced by the flow velocity v_{F} of the liquid 27 through the channel 26. Like the temperature T_{F}, the flow velocity v_{F} of the liquid 27 can also be adjusted to a setpoint value or set, in order to reach or maintain the desired temperature T_{S} of the respective photoresist layers 25a-c. In the example shown, for the sake of simplification, it is assumed that the photoresist layers 25a-c are to be heated to the same temperature T_{S}.

As shown in FIG. 2B, after the photoresist layer 25a applied to the optical surface 24a has been baked, the photoresist layer 25a is exposed, during which the photoresist layer 25a is irradiated with exposure radiation 29. The photoresist layer 25a is exposed in this case selectively only in portions intended for subsequent removal, one portion 28 of which is illustrated by way of example in FIG. 2B.

The exposure step illustrated in FIG. 2B is followed by a development step, not depicted, during which the photoresist layer 25a is developed. The development step is followed by an etching step, during which the photoresist layer 25a is structured by etching it away in the portions 25a intended for removal. FIG. 2C shows the result of such a removal, during which a grating structure 30 is formed on the collector mirror 17, only a detail of which is illustrated in FIG. 2C.

As can also be seen in FIG. 2C, oblique edges of the grating structure 30 are produced during the etching process. This has been found to be favorable for subsequent coating of the grating structure 30 with a protective layer, or with a reflective coating, as described in DE 10 2018 220 629 A1.

As illustrated in FIG. 2B, the photoresist layer 25a is also exposed in two further portions 28a, 28b which are in the vicinity of the edge of the optical surface 24a and, after the development step, during which the photoresist layer 25a is developed, and after the etching step, during which the photoresist layer 25a is structured, form, on the optical surface 24a, two position markings 32a, 32b, illustrated in FIG. 2C, for adjusting or aligning the mirror 17. Structures other than the grating structure 30 or the markings 32a, 32b may also be formed on the optical surface 24a.

The photoresist layer 25b applied to a first side face 24b of the substrate 24 also has its temperature controlled as described above and is structured with a lithographic structuring process, by exposing it in multiple portions 28c. A layer 33 made of an electrically conductive material is applied to the side face 24b of the substrate 24 underneath the photoresist layer 25b. During the structuring of the photoresist layer 25b, the underlying electrically conductive layer 33 is also structured. In the example shown, the structured electrically conductive layer forms two conductor tracks 33, which serve to actuate an electromechanical component, for example an actuator, which is not depicted. As an alternative or in addition to the electrically conductive layer 33, a structured electrically insulating layer can also be applied to the side face 24b of the substrate 24, for example in order to electrically insulate the conductor tracks 33 from the surrounding area.

The photoresist layer 25c applied to the opposite side face 24c of the substrate 24 is lithographically structured in the way described above, by exposing a portion 28d. During the structuring, a passivation layer 34 applied underneath the photoresist layer 25c is also structured, as can be seen in FIG. 2C. The structured passivation layer 34 is a polymer layer, more specifically a layer made of a polyimide in the form of Durimide®. Passivation layers made of other materials, in particular polymers, which can be lithographically structured can also be applied to the side face 24c or to another surface 24a,b, 24d of the substrate 24. The passivation layer 24 serves to protect the substrate 24 against environmental influences. The structuring of the passivation layer 34 can serve, for example, to bring the substrate 24 into direct contact with attachments in the portions that are not covered by the passivation layer 34. A possible alternative is that the photoresist layer 25c itself serves as passivation layer, for example it may be a photoresist layer which can be sintered to form SiO₂, for example the photoresist “Medusa 82”.

After the exposure of the respective layer 25a-c and before the development of the respective layer 25a-c, a baking step in the form of what is referred to as a post-exposure bake step is carried out, in order to increase the diffusion of the developed layer 25a-c. After the development of the layer 25a-c and before the etching, a further baking step (hard bake) is typically carried out to drive out residual solvents and to cure the layer 25a-c. In such a baking step (post-exposure bake or hard bake), the temperature of the collector mirror 17 can be controlled as described above in connection with FIG. 2A, i.e. by streaming the temperature-controlled liquid 27 through the collector mirror 17, or the channels 26 formed therein. During the respective baking step, the respective structured layer 25a-c is also heated to a temperature T_{S} which is of the order of magnitude of approximately 100° C. and can be reached easily using the heated liquid 27.

Owing to the control of the temperature using the channels 26 present in the substrate 24, it is not necessary to remove the collector mirror 17 from a respective processing machine to control the temperature or for baking purposes. For example, the baking can be performed before the exposure (soft bake) in a coating apparatus, in which the respective layer 25a-c is deposited on the substrate 24. The one or more baking steps after the exposure (post-exposure bake or hard bake) may be carried out for example in a coating apparatus in which the layer 25a-c is exposed.

During a step of processing the collector mirror 17, during which parasitic heat arises, for example during an etching step that follows the hard bake step or during plasma cleaning, temperature control in the form of cooling of the collector mirror 17 can be carried out. The cooling is performed similarly to the heating described above, except that the temperature T_{F} of the liquid 27 flowing through the channel 26 is generally between approximately 10° C. and approximately 50° C. during the cooling operation.

The method described above is not restricted to the processing of a (collector) mirror 17, but can also be used advantageously on other workpieces which need to have their temperature controlled. It is also not necessary for the processing of the workpiece to be a photolithographic structuring of the workpiece: Other processing processes may also require temperature control, i.e. heating or cooling, of the workpiece.

What is claimed is:

1. A method for processing a workpiece in a processing process, comprising:
controlling a temperature of the workpiece,
by streaming a fluid through at least one channel formed inside the workpiece.

2. The method according to claim 1, wherein the processing process comprises a photolithographic structuring process.

3. The method as claimed in claim 1, further comprising:
baking at least one layer while the temperature of the workpiece is being controlled in at least one baking step, and
applying the at least one layer to the workpiece.

4. The method as claimed in claim 3, wherein the processing process comprises a photolithographic structuring process and the layer is a photoresist layer for structuring in the photolithographic structuring process.

5. The method as claimed in claim 4, further comprising:
exposing the photoresist layer to drive solvent out of the photoresist layer,
wherein said baking is carried out before said exposing.

6. The method as claimed in claim 4, further comprising:
exposing the photoresist layer,
wherein said baking is carried out after said exposing.

7. The method as claimed in claim 3, wherein the workpiece is a mirror and wherein said applying of the layer comprises applying the layer to a surface of the mirror.

8. The method as claimed in claim 7, wherein said applying comprises applying the layer to an optical surface of the mirror.

9. The method as claimed in claim 7, wherein the mirror comprises a substrate, further comprising:
forming the at least one channel in the substrate.

10. The method as claimed in claim 7, further comprising:
structuring the layer to form a structure on the surface of the mirror.

11. The method as claimed in claim 7, wherein said structuring of the layer forms a grating structure and/or at least one marking on the surface of the mirror.

12. The method as claimed in claim 7, wherein said structuring of the layer forms at least one structured electrically conductive or electrically insulating layer on the surface of the mirror.

13. The method as claimed in claim 10, wherein said structuring of the layer forms at least one structured passivation layer on the surface of the mirror.

14. The method as claimed in claim 11, wherein the mirror is configured as an extreme ultraviolet (EUV) lithography mirror.

15. The method as claimed in claim 14, wherein the grating structure on the mirror forms a spectral filter.

16. The method as claimed in claim 1, further comprising:
controlling a temperature (T_{F}) of the fluid streaming through the at least one channel to at least 60° C. and no more than 120° C.

17. The method as claimed in claim 16, wherein said adjusting comprises controlling the temperature of the fluid to at least 80° C. and no more than 110° C.

18. The method as claimed in claim 1, further comprising:
controlling a temperature (T_{F}) and/or a flow velocity (v_{F}) of the fluid streaming through the at least one channel to a predefined value.
